(19) United States
(12) Patent Application Publication
(10) Pub. No.: US 2009/0206056 A1
(43) Pub. Date: Aug. 20, 2009

(54) Method and Apparatus for Plasma Process Performance Matching in Multiple Wafer Chambers

(76) Inventors: Songlin Xu, Fremont, CA (US); Daniel J. Devine, Los Gatos, CA (US); Wen Ma, Fremont, CA (US); Ce Qin, Fremont, CA (US); Vijay Vaniapura, Los Altos, CA (US)

Correspondence Address: PRITZKAU PATENT GROUP, LLC, 993 GAPTER ROAD, BOULDER, CO, 80303, US

(21) Appl. No.: 12/367,488

(22) Filed: Feb. 6, 2009

Related U.S. Application Data
(60) Provisional application No. 61/028,899, filed on Feb. 14, 2008.

(51) Int. Cl. C23F 1/00; C23F 1/08; B05C 11/00; C23C 16/52

(52) U.S. Cl. 216/59; 156/345.26; 118/663; 427/8

(57) ABSTRACT

A multi-station workpiece processing system provides a targeted equal share of a regulated input process gas flow to each active processing station of a plurality of active processing stations using a single gas flow regulator for each gas and irrespective of the number of inactive processing stations.

### RELATED APPLICATION

The present application claims priority from U.S. Provisional Patent Application Ser. No. 61/028,899, filed on Feb. 14, 2008, the contents of which are incorporated herein by reference.

### BACKGROUND

Processing two (or more) wafers at a time in a single plasma processing chamber using only a single gas supply and single vacuum pump is an approach that has been successful in reducing system size and cost per wafer processed. As is well known, the single gas supply provides a suitable regulator mechanism for each different type of gas that is in use or a single regulator mechanism in the instance of using premixed gases. This is the case currently in a prior art dual-compartment or dual-head chamber sharing a common gas supply line for performing processes such as, for example, etching and deposition. FIG. 1 diagrammatically illustrates such a system, generally indicated by the reference number 100. In such systems where multiple wafers may be processed at the same time in a chamber with a single gas supply control, there is normally a difference in the process performance of a plasma mediated process, such as etch rate or deposition rate, observed when only one wafer is processed versus when two or more wafers are processed simultaneously. Processing of a single wafer with inactive heads in a multi station process chamber occurs often in mass production of semiconductors since a normal cassette full or batch of wafers will have an odd number of wafers, resulting in the need to process a single wafer at least once each cassette. In the exemplary case where the etching rate differs for single wafer at-a-time versus when two wafers are simultaneously processed, the result can in one case or the other be unacceptable for proper circuit function, resulting in reduced IC yield. Applicants recognize that a solution for this issue is needed in order to provide for consistent plasma process performance on every wafer during production.

The foregoing examples of the related art and limitations related therewith are intended to be illustrative and not exclusive. Other limitations of the related art will become apparent to those of skill in the art upon a reading of the specification and a study of the drawings.

### SUMMARY

The following embodiments and aspects thereof are described and illustrated in conjunction with systems, tools and methods which are meant to be exemplary and illustrative, not limiting in scope. In various embodiments, one or more of the above-described problems have been reduced or eliminated, while other embodiments are directed to other improvements.

In general, a multi-station workpiece processing system includes a single chamber having at least two processing stations for simultaneously processing two or more workpieces with one workpiece located at each station. At least one workpiece is processed at one active one of the processing stations with at least one other one of the processing stations inactive. Each of the processing stations includes a plasma generator that receives a processing station gas supply for use in generating a plasma to treat a particular workpiece at that processing station.

In one aspect of the disclosure, at least a portion of the processing station gas supply, that is released in the plasma generator at a given one of the processing stations, is capable of flowing, as a cross-flow, to at least one other one of the processing stations through the chamber arrangement, irrespective of whether the given processing station is active or inactive. The system is configured for producing a full workload gas flow that is distributed to all the processing stations from an overall gas input to produce the processing station gas supply for the plasma generator of each processing station such that each processing station receives, at least approximately, a target equal share of the full workload gas flow, as the processing station gas supply, when all of the processing stations are active. Less than the total number of processing stations are selected as active processing stations such that at least one processing station is selected to actively process a workpiece while at least one other one of the processing stations is inactive and does not process a workpiece. The gas supply to each inactive process station is terminated. Corresponding to each inactive processing station, the full workload gas flow is reduced by an amount that is approximately equal to the full workload gas flow divided by the total number of processing stations to produce a current gas flow, at the overall gas input, that is distributed among the active processing stations such that each active processing station receives, at least approximately, the target equal share of the current gas flow, irrespective of the inactive processing stations, and the cross-flow from inactive ones of the processing stations to active ones of the processing stations is eliminated such that a cross-flow related process influence at the active processing stations, which would otherwise be produced by emitting the processing station gas supply at the inactive processing stations, is eliminated.

In another aspect of the disclosure, at least a portion of the processing station gas supply, that is released at a given one of the processing stations, is capable of flowing, as a cross-flow, to at least one other one of the processing stations through the chamber arrangement, irrespective of whether the given processing station is active or inactive. The system is configured for producing a full workload gas flow that is distributed to all the processing stations from an overall gas input such that each processing station receives, at least approximately, a target equal share of the full workload gas flow when all of the processing stations are active. An apparatus, forming part of the system, provides for processing at least one workpiece at one active one of the processing stations with at least one other one of the processing stations inactive. The apparatus includes a user input arrangement for allowing an operator of the system to electronically select less than the total number of processing stations as active processing stations such that at least one processing station is selected to actively process a workpiece while at least one other one of the processing stations is inactive and does not process a workpiece. A control arrangement, responsive to the user input arrangement, generates at least one control signal to electrically terminate the processing station gas supply to each inactive process stations and reduces the full workload gas flow, corresponding to each inactive processing station, by an amount that is approximately equal to the full workload gas flow divided by the total number of processing stations to produce a current gas flow, at the overall gas input, that is distributed among the active processing stations such that each one of the active processing stations receives, at least approximately, the target equal share of the current gas flow, irrespective of the inactive processing stations, and the cross-flow from inactive ones of the processing stations to active ones of the processing stations is eliminated such that a cross-flow related process influence at the active processing stations, which would otherwise be produced by emitting the processing station gas supply at the inactive processing stations, is eliminated.

In still another aspect of the present disclosure, the system is configured for producing a full workload gas flow that is regulated and then distributed to all the processing stations from an overall gas input to produce the processing station gas supply for the plasma generator of each processing station such that the processing station gas supply to each individual processing station is not regulated and each processing station receives, at least approximately, a target equal share of the full workload gas flow, as the processing station gas supply, when all of the processing stations are active. Less than the total number of processing stations are selected as active processing stations such that at least one processing station is selected to actively process a workpiece while at least one other one of the processing stations is inactive and does not produce a plasma so that each inactive processing station would cause a difference in gas conductance relative to the active processing stations which would unevenly split the full workload gas flow between the processing stations. The gas supply to the inactive process stations is terminated. Corresponding to each inactive processing station, the full workload gas flow is reduced by an amount that is approximately equal to the full workload gas flow divided by the total number of processing stations to produce a current gas flow, at the overall gas input, that is distributed among the active processing stations without individual regulation of each processing station gas flow for each processing station such that each active processing station receives, at least approximately, the target equal share of the current gas flow, by eliminating the difference in gas conductance that would otherwise be caused each of the inactive processing stations.

In yet another aspect of the present disclosure, the system is configured for producing a full workload gas flow that is regulated and then distributed to all the processing stations from an overall gas input to produce the processing station gas supply for the plasma generator of each processing station such that the processing station gas supply to each individual processing station is not regulated and each processing station receives, at least approximately, a target equal share of the full workload gas flow when all of the processing stations are active. A control arrangement is configured for electronically selecting less than the total number of processing stations as active processing stations with at least one processing station selected to actively process a workpiece while at least one other one of the processing stations is inactive and does not produce a plasma such that each inactive processing station would cause a difference in gas conductance relative to each of the active processing stations which would unevenly split the full workload gas flow between the processing stations, and for generating at least one control signal to electrically terminate the processing station gas supply to each inactive process station. The control arrangement is further configured for reducing the full workload gas flow, corresponding to each inactive processing station, by an amount that is approximately equal to the full workload gas flow divided by the total number of processing stations to produce a current gas flow, at the overall gas input, that is distributed among the active processing stations without individual regulation of each processing station gas flow for each processing station such that each active processing station receives, at least approximately, the target equal share of the current gas flow, irrespective of the inactive processing stations, by eliminating the difference in gas conductance that would otherwise be caused by each inactive processing station emitting process gas.

In addition to the exemplary aspects and embodiments described above, further aspects and embodiments will become apparent by reference to the drawings and by study of the following descriptions.

### BRIEF DESCRIPTION OF THE DRAWINGS

Exemplary embodiments are illustrated in referenced figures of the drawings. It is intended that the embodiments and figures disclosed herein are to be illustrative rather than limiting.

FIG. 1 is a diagrammatic illustration of a prior art processing system having side-by-side processing stations in a shared chamber, shown here to illustrate details of its operation and structure.

FIG. 2 is a diagrammatic illustration of a processing system configured having side-by-side processing stations in a shared chamber, shown here to illustrate details of its operation and structure according to the present disclosure.

FIG. 3 is a flow diagram illustrating one embodiment of a method according to the present disclosure.

FIG. 4 is a table which compares prior art processing results with processing results obtained through the practice of the present disclosure.

### DETAILED DESCRIPTION

The following description is presented to enable one of ordinary skill in the art to make and use the invention and is provided in the context of a patent application and its requirements. Various modifications to the described embodiments will be readily apparent to those skilled in the art and the generic principles taught herein may be applied to other embodiments. Thus, the present invention is not intended to be limited to the embodiment shown, but is to be accorded the widest scope consistent with the principles and features described herein including modifications and equivalents, as defined within the scope of the appended claims. It is noted that the drawings are not to scale and are diagrammatic in nature in a way that is thought to best illustrate features of interest. For purposes of this disclosure, the terms “processing station” and “head” may be used interchangeably in reference to the location and associated hardware that is utilized to treat one workpiece such as, for example, a semiconductor wafer. Descriptive terminology may be adopted for purposes of enhancing the reader's understanding, with respect to the various views provided in the figures, and is in no way intended as being limiting.

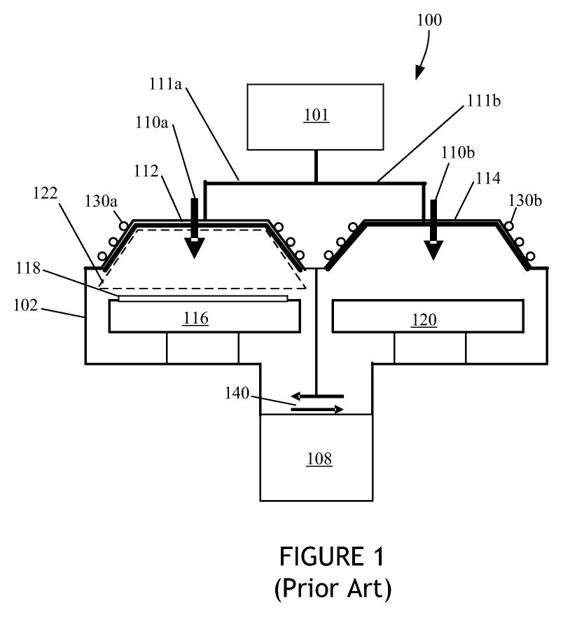

As will be further described and in view of the prior art system of FIG. 1, Applicants have found a contributing cause for a difference in plasma processing rates when at least one processing station is inactive in a multiple processing station chamber. In the context of a dual processing chamber by way of non-limiting example, while a total workload gas flow splits or divides equally into two heads in the chamber when two wafers are being processed such that each head receives a target equal share of the full workload gas flow, the divide becomes unequal for the different heads when only one wafer is being processed such that the active head does not receive its target equal share of the full workload gas flow. While not intending to be bound by theory, this is believed to be due in part to a variation in conductance of molecular gas(es) when they are dissociated by the plasma. In the case where there is plasma and processing taking place on only one side in the system, the gas conductance or conductance path is different on that side from the gas conductance on the other side having no plasma. One of ordinary skill in the art will recognize that gas conductance is related to the resistance of a channel to gas flow. This difference in conductance causes gas flow to split unevenly between the two sides. Consequently, the rate of the plasma process will change depending on whether only one head is using plasma versus when both heads are using plasma. In one embodiment, an on/off valve is added in the split gas line to each head. For two wafer processing, both valves are opened. But for single wafer processing, only the valve to the head with the wafer is open and the other valve is closed. At the same time, the total gas flow is cut in half for single wafer processing so the flow to the head with wafer remains unchanged at its targeted equal share compared to that when two wafers are processing. This has surprisingly been found to work very well even when gas can flow between the two or more processing regions internal to the processing chamber arrangement, such as may be the case in multiple wafer processing reactors utilizing a single vacuum pump and gas supply.

Attention is now directed to the views of the various figures wherein like reference numbers may be applied to like items when practical. Whereas in prior art processing system 100 of FIG. 1, gas from a source 101 is injected into a chamber 102, and pumped by a common vacuum pump 108, the gas always flows in nearly equal proportions 110a and 110b through lines 111a and 111b, respectively, into processing stations 112 and 114 when two wafers are being processed. It has been found, however, that this full workload gas flow divides less equally when only one pedestal 116 in station 112 supports a wafer 118 and a pedestal 120 of station 106 does not support a wafer, since this station is idle and is not producing a plasma. That is, station 112 contains a plasma 122 (indicated using dashed lines) that is produced by a plasma source 130a while a plasma source 130b of station 114 is idle. This prior art system has no valves or flow regulation devices between gas supply 101 and the process chamber and therefore, the distribution of the gas flow cannot be controlled separately with respect to the two process stations, depending on whether wafers are to be processed in one or both stations. Stated in a slightly different way, regulated gas is supplied from a single regulation mechanism collectively to the plurality of processing stations as a total gas flow. The system is not able to individually regulate the process gas supply for each processing station. When a station is inactive and not generating a plasma, process gas from that station can produce a cross-flow 140 to the active station as illustrated by arrows. The resulting difference in processing results will be discussed at an appropriate point below.

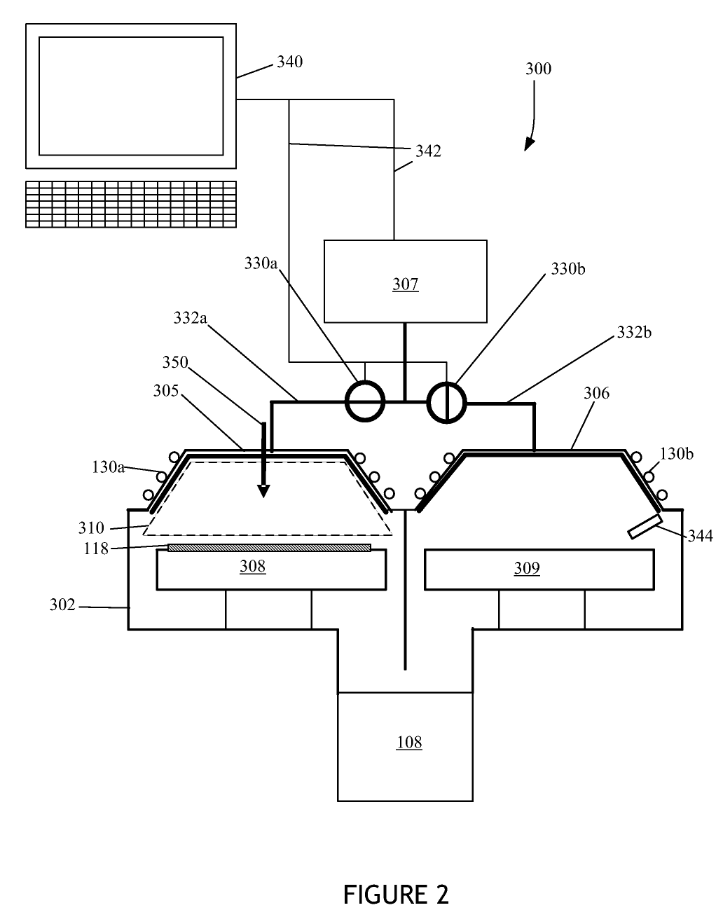

In FIG. 2, one embodiment of a processing system, generally indicated by the reference number 300, is diagrammatically shown by way of non-limiting example having a processing chamber 302 in which side-by-side processing stations 305 and 306, respectively, receive processing gas from a gas supply 307 that can be an MFC (Mass Flow Controller) or any suitable arrangement for providing a selectable processing gas flow. Vacuum pump 108 and an associated pumping port are shared by the processing stations. Pedestals 308 and 309 can each support a workpiece such as, for example, a semiconductor wafer at each processing station. Any suitable type of pedestal can be used such as, for example, one having an electrostatic chuck. In the present example, workpiece 118 is supported at station 308 while station 309 is inactive. The processing stations include plasma generators 130a and 130b with the former producing a plasma 310 (indicated by dashed lines) from the process gas flow. That is, only the plasma generator for station 305 is producing a plasma from the process gas flow for purposes of this example. Further, valves 330a and 330b have been provided in gas lines 332a and 332b leading from gas supply 307 to the respective plasma sources of the processing stations. These valves permit the gas, for example, to station 306 to be stopped while still flowing one-half the previous total flow from source 307, as compared to when two wafers are being processed at the same time, and directing the flow to active head 305. In the present example, valve 330b is illustrated in a closed position with processing station 306 inactive while processing station 305 is active with valve 330a open. A control system 340 controls both the total gas supply by providing control signals on lines 342 and whether valves 330a and 330b are either open or closed by generating control signals that are likewise provided on lines 342. As an example, this control can be implemented using electrical lines 342. The output of gas supply 307 serves as an overall gas input to the processing stations. In one embodiment, the control arrangement can respond to a user input for purposes of identifying and selecting inactive processing stations by terminating gas flow to the inactive station or stations and adjust the remaining total output of flow controller 307 such that a current, remaining gas flow divides among the active processing stations to match the targeted gas flow, irrespective of the inactive station or stations. A sensor 344, which is diagrammatically illustrated, is configured for detecting whether a wafer is going to be processed and/or is present on pedestal 309 and may be of any suitable type such as, for example, a vacuum sensor or a laser sensor. An electrical connection for the sensor to control system 340 has not been shown for purposes of illustrative clarity, but is understood to be present. While only one station is shown having a wafer detector, it should be appreciated that any station in an overall plurality of two or more stations can be configured with a wafer detector for control purposes. In another embodiment, control system 340 can automatically respond to sensor signals to terminate gas flow to one or more inactive heads and adjust the remaining total gas flow so that each active head receives its targeted gas flow. An arrow 350 illustrates a magnitude of process gas flow into station 305 that matches the level that would be seen if both stations were active. Accordingly, cross-flow 120 in FIG. 1 has been advantageously eliminated, at least from a practical standpoint. As in the FIG. 1 prior art system, there is still a single gas supply and a single vacuum pump is used for processing two wafers at one time while providing for improved processing of a single wafer. This efficiency of use of a single chamber with single gas supply and single pump for simultaneously processing two wafers utilizes less space and at lower total cost than two normal processing chambers and therefore lowers cost of the process—critical for mass production of integrated circuits. It should be appreciated that the ability to use a single gas regulation apparatus such as, for example, an MFC in a multiple processing station arrangement and irrespective of the total number of processing stations can avoid a significant increase in cost and reliability.

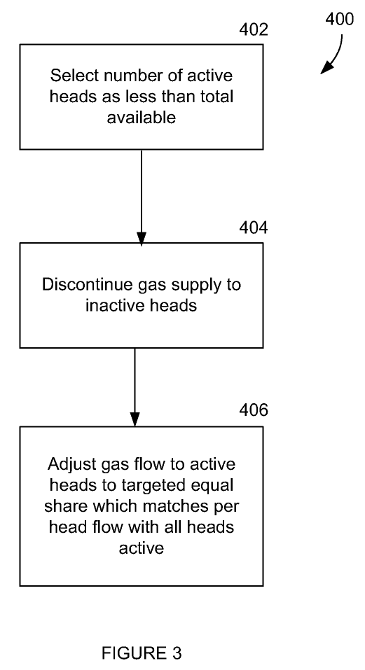

FIG. 3 illustrates one embodiment of a process, generally indicated by the reference number 400, that can be implemented by control system 340 in which the number of heads selected to be active is less than the total number of heads that is available at step 402. At 404, the gas supply is then discontinued to the inactive heads, for example, by closing valves in the plasma gas supply lines that lead to those heads. At 406, the plasma gas flow to the active heads is then adjusted or modified to match a targeted equal share of the overall gas flow that would match per head flow with all heads active. For example, if the total flow with both heads active in a two head system is 2×, the targeted flow for one active head is 1×. As another example, with three heads available and with a total gas flow of 3× with all three heads active, the targeted per head flow is 1×. Therefore, if two heads are active, a total gas flow of 2× is needed with 1× flowing to each active head. It should be appreciated that the targeted flow for each active head will be matched at least approximately. The latter term is intended to account for essentially unavoidable performance capabilities of regulation mechanisms such as, for example, tolerance ratings of MFCs and minor performance differences that might be caused, for example, by gas piping.

In one embodiment, control system 340 can be configured for accepting inputs from a user to identify processing status such as, for example, one or more inactive stations. The control system can then respond accordingly in terms of terminating the gas flow to each inactive station and adjusting the total process gas flow. In another embodiment, the controller can use detectors of any suitable type such as, for example, sensor 344 to detect that a wafer is not present at one or more stations, automatically terminate the gas flow to the inactive stations and automatically adjust the gas flow for the active stations in accordance with this disclosure.

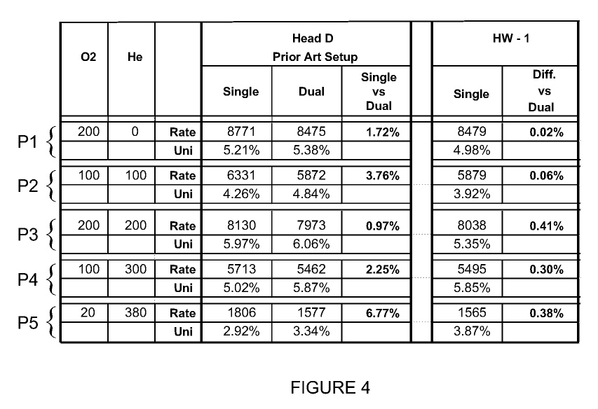

FIG. 4 is a table which illustrates empirically obtained processing results in the context of prior art FIG. 1 for comparison with results obtained based on the teachings of this disclosure which are also illustrated. In particular, processes P1-P6 were applied using different mixtures of oxygen and helium to form a plasma that was used for etching. Aside from the variation in process gas mixtures other processing conditions were maintained to match, at least from a practical standpoint, from one process to the next. In particular, the pressure was 10 milliTorr, the power to each plasma source was 2,500 watts, the power to each active workpiece pedestal was 225 watts and the temperature was 25 degrees Centigrade. The differing gas mixtures are shown by an oxygen (O₂) column and a helium (He) column. The “Head D” column lists results obtained using a prior art processing setup such as in FIG. 1. Process results are given for operation of a single station (the “Single” column) in the two station system treating (i.e., processing) a single wafer, as compared to operation of both stations (the “Dual” column), in which both stations are active with each station treating a wafer. For the single station results, gas flow was maintained to the inactive station in the manner of the prior art. Etch rate as Angstroms per minute is given for each process as well as process uniformity as a percentage. A “Single vs Dual” column indicates the difference in etch rate, as a percentage, between processing a single wafer versus processing two wafers. The data shows that there is between about a one percent and a seven percent difference between etching rates for wafers processed two at a time versus one at a time without separate gas control such that process gas continues to flow into the unused or inactive station without regulation specific to its processing station when a workpiece is processed using at least one other station.

Still referring to FIG. 4, a column labeled as “HW-1” provides process results obtained using a system configured in accordance with the teachings herein such that gas flow to the inactive station is terminated and gas flow to the active head is adjusted. Etch rates and process uniformity as a percentage are shown in a manner that is consistent with the listings under the Head D column. Further, a “Diff. vs Dual” column indicates a percentage difference in etch rate for each set of process gas mixtures by comparing the Single station results under the HW-1 column to the dual processing results in the Dual column under Head D. Remarkably, there is less than about a 0.4% difference between wafers processed two at a time versus one at a time achieved by practicing the teachings herein.

As discussed immediately above, the teachings can be extended to a chamber with more than two compartments or stations within the same chamber for multiple wafer processing. The valve on each split gas line can selectively and completely stop the flow to each head so that an existing flow control system such as a mass flow controller can reduce the gas input by an appropriate fraction to the heads that are in use, based on the number of active/inactive heads. In the example of FIG. 4, one MFC would be needed for oxygen and another MFC would be needed for helium. As a continuation of the foregoing example using three heads, if there are three heads and one head is inactive, total flow to the chamber will be reduced to ⅔ of the previous flow and will be equally divided by way of unregulated distribution between the two active heads with the valve to the inactive head closed and the remaining two heads receiving ⅔ of the previous gas flow. If only one head is active out of three, that head will receive ⅓ of the gas flow that would otherwise have been provided to all three heads, if active.

The foregoing description of the invention has been presented for purposes of illustration and description. For example, some of the descriptions are framed in terms of the improvement of an etching process, however, the teachings herein are applicable to plasma mediated processes in general and include etching, deposition and the like. In this regard, the disclosure is not intended to be exhaustive or to limit the invention to the precise form or forms disclosed, and other modifications and variations may be possible in light of the above teachings wherein those of skill in the art will recognize certain modifications, permutations, additions and sub-combinations thereof.

What is claimed is:

1. In a multi-station workpiece processing system having a single chamber including at least two processing stations for simultaneously processing two or more workpieces with one workpiece located at each station, a method for processing at least one workpiece at one active one of the processing stations with at least one other one of the processing stations inactive, each of said processing stations including a plasma generator that receives a processing station gas supply for use in generating a plasma to treat a particular workpiece at that processing station, and wherein at least a portion of said processing station gas supply, that is released in the plasma generator at a given one of the processing stations, is capable of flowing, as a cross-flow, to at least one other one of the processing stations through the chamber arrangement, irrespective of whether the given processing station is active or inactive, said system further being configured for producing a full workload gas flow that is distributed to all the processing stations from an overall gas input to produce said processing station gas supply for the plasma generator of each processing station such that each processing station receives, at least approximately, a target equal share of the full workload gas flow, as said processing station gas supply, when all of the processing stations are active, said method comprising:
selecting less than said total number of processing stations as active processing stations such that at least one processing station is selected to actively process a workpiece while at least one other one of the processing stations is inactive and does not process a workpiece;
terminating the gas supply to the inactive process stations;
corresponding to each inactive processing station, reducing the full workload gas flow by an amount that is approximately equal to the full workload gas flow divided by the total number of processing stations to produce a current gas flow, at the overall gas input, that is distributed among the active processing stations such that each active processing station receives, at least approximately, said target equal share of the current gas flow, irrespective of the inactive processing stations, and said cross-flow from inactive ones of the processing stations to active ones of the processing stations is eliminated such that a cross-flow related process influence at the active processing stations, which would otherwise be produced by emitting the processing station gas supply at the inactive processing stations, is eliminated. This eliminates the need for separate sets of flow controllers to each process station.

2. In a multi-station workpiece processing system having a chamber arrangement including a total number of at least two processing stations for simultaneously processing two or more workpieces with one workpiece located at each station, each of said processing stations including a plasma generator that receives a processing station gas supply for use in generating a plasma to treat a particular workpiece at that processing station, and wherein at least a portion of said processing station gas supply, that is released at a given one of the processing stations, is capable of flowing, as a cross-flow, to at least one other one of the processing stations through the chamber arrangement, irrespective of whether the given processing station is active or inactive, said system further being configured for producing a full workload gas flow that is distributed to all the processing stations from an overall gas input such that each processing station receives, at least approximately, a target equal share of the full workload gas flow when all of the processing stations are active, an apparatus, forming part of said system, providing for processing at least one workpiece at one active one of the processing stations with at least one other one of the processing stations inactive, said apparatus comprising:
a user input arrangement for allowing an operator of said system to electronically select less than the total number of processing stations as active processing stations such that at least one processing station is selected to actively process a workpiece while at least one other one of the processing stations is inactive and does not process a workpiece; and
a control arrangement, responsive to said user input arrangement, for generating at least one control signal to electrically terminate the processing station gas supply to each inactive process stations and for reducing the full workload gas flow, corresponding to each inactive processing station, by an amount that is approximately equal to the full workload gas flow divided by the total number of processing stations to produce a current gas flow, at the overall gas input, that is distributed among the active processing stations such that each one of the active processing stations receives, at least approximately, said target equal share of the current gas flow, irrespective of the inactive processing stations, and said cross-flow from inactive ones of the processing stations to active ones of the processing stations is eliminated such that a cross-flow related process influence at the active processing stations, which would otherwise be produced by emitting the processing station gas supply at the inactive processing stations, is eliminated.

3. In a multi-station workpiece processing system having a single chamber including at least two processing stations for simultaneously processing two or more workpieces with one workpiece located at each station, a method for processing the workpiece at each active one of the processing stations with at least one other one of the processing stations inactive, each of said processing stations including a plasma generator that receives a processing station gas supply for use in generating a plasma to treat a particular workpiece at that processing station, said system further being configured for producing a full workload gas flow that is regulated and then distributed to all the processing stations from an overall gas input to produce said processing station gas supply for the plasma generator of each processing station such that the processing station gas supply to each individual processing station is not regulated and each processing station receives, at least approximately, a target equal share of the full workload gas flow, as said processing station gas supply, when all of the processing stations are active and generating plasma, said method comprising:
selecting less than said total number of processing stations as active processing stations such that at least one processing station is selected to actively process a workpiece while at least one other one of the processing stations is inactive and does not produce a plasma so that each inactive processing station would cause a difference in gas conductance relative to the active processing stations which would unevenly divide the full workload gas flow between the processing stations;
terminating the gas supply to the inactive process stations; and
corresponding to each inactive processing station, reducing the full workload gas flow by an amount that is approximately equal to the full workload gas flow divided by the total number of processing stations to produce a current gas flow, at the overall gas input, that is distributed among the active processing stations without individual regulation of each processing station gas flow for each processing station such that each active processing station receives, at least approximately, said target equal share of the current gas flow, by eliminating the difference in gas conductance that would otherwise be caused by each one of the inactive processing stations.

4. The method of claim 4 further comprising:
sensing for the presence of a workpiece at a given one of the processing stations to indicate that the given one of the processing stations is inactive when a workpiece is not present and wherein said terminating responds to said sensing by automatically terminating the gas flow to the given processing station, and said reducing automatically decreases the current gas flow so that each active processing station receives said target equal share.

5. The method of claim 4 further comprising:
providing a user input arrangement for accepting a user input that indicates that at least a given one of the processing stations is inactive, and
said terminating responds to the user input by automatically terminating the gas flow to the given processing station and said reducing automatically decreases the current gas flow so that each active processing station receives said target equal share.

6. In a multi-station workpiece processing system having a chamber arrangement including a total number of at least two processing stations for simultaneously processing two or more workpieces with one workpiece located at each station, each of said processing stations including a plasma generator that receives a processing station gas supply for use in generating a plasma to treat a particular workpiece at that processing station, and said system further being configured for producing a full workload gas flow that is regulated and then distributed to all the processing stations from an overall gas input to produce said processing station gas supply for the plasma generator of each processing station such that the processing station gas supply to each individual processing station is not regulated and each processing station receives, at least approximately, a target equal share of the full workload gas flow when all of the processing stations are active, an apparatus comprising:
a control arrangement for electronically selecting less than the total number of processing stations as active processing stations with at least one processing station selected to actively process a workpiece while at least one other one of the processing stations is inactive and does not produce a plasma such that each inactive processing station would cause a difference in gas conductance relative to each of the active processing stations which would unevenly split the full workload gas flow between the processing stations, and for generating at least one control signal to electrically terminate the processing station gas supply to each inactive process station and reducing the full workload gas flow, corresponding to each inactive processing station, by an amount that is approximately equal to the full workload gas flow divided by the total number of processing stations to produce a current gas flow, at the overall gas input, that is distributed among the active processing stations without individual regulation of each processing station gas flow for each processing station such that each active processing station receives, at least approximately, said target equal share of the current gas flow, irrespective of the inactive processing stations, by eliminating the difference in gas conductance that would otherwise be caused by each of the inactive processing stations emitting process gas.

7. The apparatus of claim 6 further comprising:
a sensing arrangement including at least one sensor responsive to the presence of a workpiece at a given one of the processing stations to provide an indication that the given one of the processing stations is inactive when one workpiece is not present and said control arrangement is configured to respond to said indication by automatically terminating the gas flow to the given processing station and automatically decreasing the current gas flow so that each active processing station receives said target equal share.

8. The apparatus of claim 6 further comprising:
a user input arrangement for accepting a user input that indicates that at least a given one of the processing stations is inactive and said control arrangement is configured to respond to the user input by automatically terminating the gas flow to the given processing station and automatically decreasing the current gas flow so that each active processing station receives said target equal share.

9. The apparatus of claim 6 further comprising:
a plurality of gas supply lines such that one of the gas supply lines leads from the overall gas input to the plasma generator of each one of the processing stations; and
a plurality of electrically actuatable control valves each of which is in electrical communication with said control arrangement such that the control arrangement can selectively open and close each one of the control valves to selectively provide process gas to each processing station responsive to said control arrangement.

10. The apparatus of claim 6 wherein said workpieces are semiconductor wafers.
